(19) United States
(12) Patent Application Publication
(10) Pub. No.: US 2002/0154471 A1
(43) Pub. Date: Oct. 24, 2002

(54) Self-contained electronic surrogate presence

(76) Inventor: Thomas E. Miller, Savoy, IL (US)

Correspondence Address: Thomas E. Miller, 6 Hartwell Court, Apartment 9, Savoy, IL, 61874, US

(21) Appl. No.: 09/839,093

(22) Filed: Apr. 23, 2001

(51) Int. Cl. H05K 5/00

(52) U.S. Cl. 361/679; 361/683

(57) ABSTRACT

The research conducted by the inventor identified several aspects of the Digital Age that have failed to reach its true potentional. The Self-Contained Electronic Surrogate Presence was created as an ecologically conscious communication and learning tool linking the digital and analog generations. This device is stripped of all non-essential hardware, including the plastic case, easing the immense recycling burden wholesale planned obsolescence has wrought. The device is composed of modular components that are specifically tailored to a particular task. The Self-Contained Electronic Surrogate Presence is designed to take the place of sending documents and personnel to conduct business and to address the cultural need for a presence, virtually. The Self-Contained Electronic Surrogate Presence is controlled by the sender and is tailored to perform the required task otherwise performed by an individual.

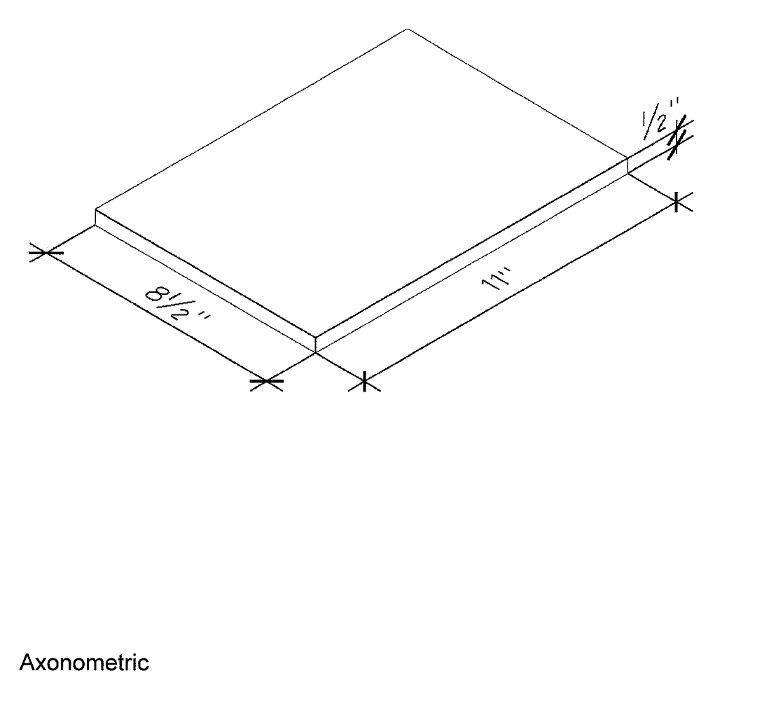

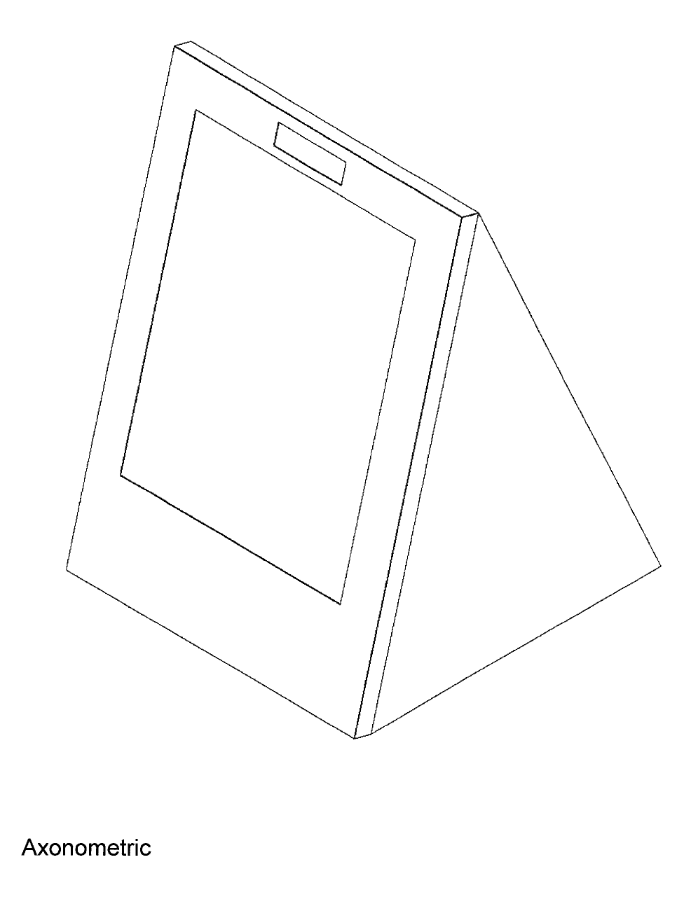

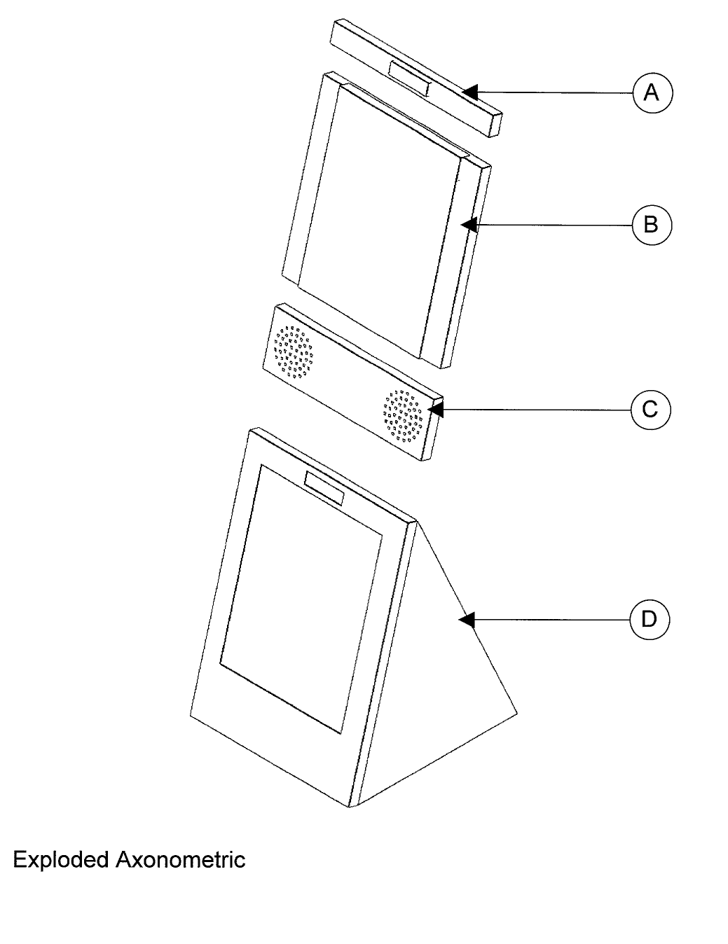

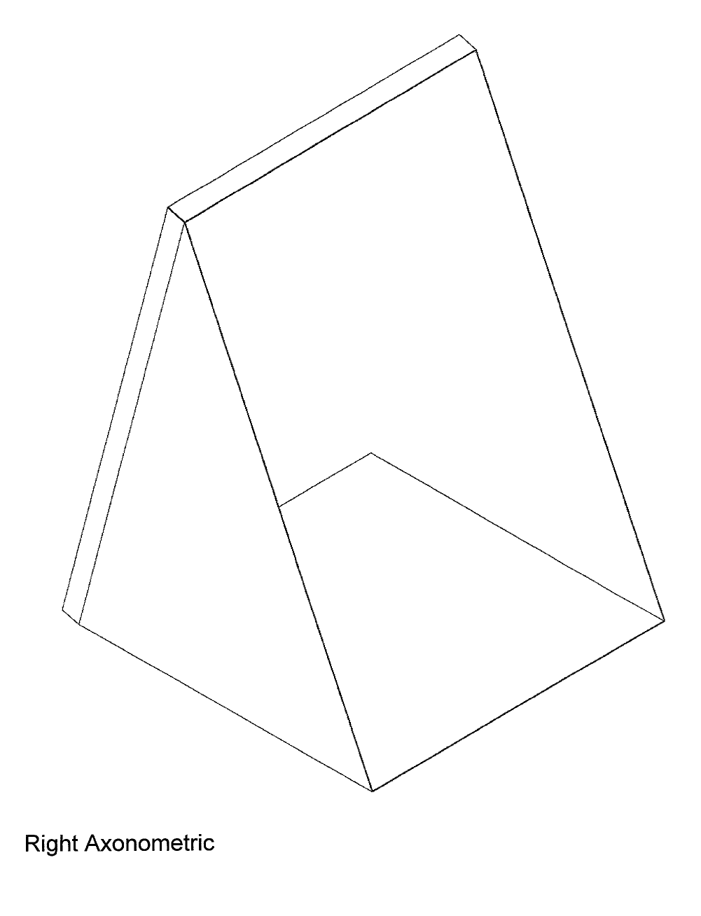

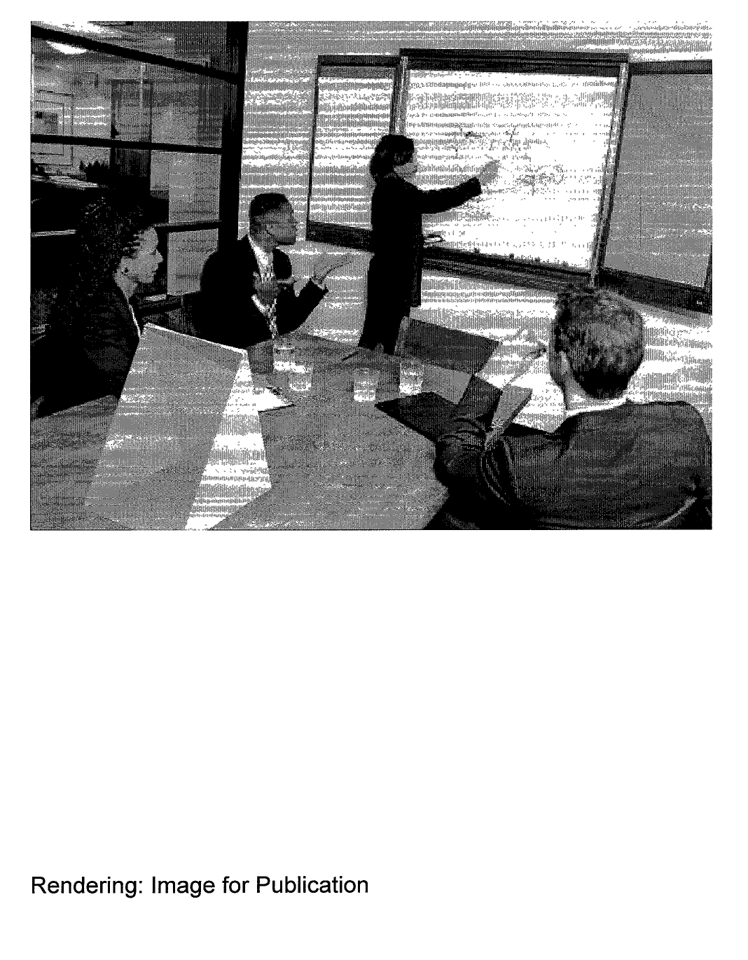

### CROSS REFERENCE TO RELATED APPLICATIONS

Not Applicable

### STATEMENT REGARDING FEDERALLY SPONSORED RESEARCH OR DEVELOPMENT

Not Applicable

### REFERENCE TO MICROFICHE APPENDIX

Not Applicable

### BACKGROUND OF INVENTION

The research conducted by the inventor identified several aspects of the Digital Age that have failed to reach its true potentional. The “digital revolution” has left more people behind than brought with it. Dreams about less travel, increased efficiency, and an ecologically sustainable lifestyle have been dashed by a redundant, fractured reality. The Self-Contained Electronic Surrogate Presence was created as an ecologically conscious communication and learning tool linking the digital and analog generations. This device is stripped of all non-essential hardware, including the plastic case, easing the immense recycling burden wholesale planned obsolescence has wrought. The device is composed of modular components that are specifically tailored to a particular task. Current state of the art video conferencing relies heavily on the compatibility of the involved parties' hardware and software as well as the infrastructure that separates them as well as the level of familiarity of both parties with the tools at hand. The societal importance of face-to-face communication has vastly curtailed the many of economies of the digital age. The Self-Contained Electronic Surrogate Presence is designed to take the place of sending documents and personnel to conduct business and to address the cultural need for a presence, virtually. The Self-Contained Electronic Surrogate Presence is controlled by the sender and is tailored to perform the required task otherwise performed by an individual.

### BRIEF DESCRIPTION OF SEVERAL VIEWS OF THE DRAWINGS

1/5: Axonometric, Shows the device folded flat unassembled for shipping.

2/5: Axonometric, Shows the device unfolded ready for use.

3/5: Exploded Axonometric. Shows the various components that make up the unit. A) Visualization Module B) Display Module, C) Task Module, Power, and Speaker Assembly, D) Packing/Housing.

4/5: Right Axonometric, Shows the back of the unit, unfolded ready for use.

5/5: Perspective view for publication.

### DETAILED DESCRIPTION OF THE INVENTION

The Self-Contained Electronic Surrogate Presence is a new integrated business model and software/hardware paradigm that leverages existing infrastructure and existing understanding. This creates a new post personal computer device that acts as a surrogate presence for the initiator of the unit. The device is rented online and shipped locally, partnering with an existing global shipping company. The transaction is handled online and the information is stored in extensible market language (XML), and the product is shipped from a local distribution site. Once the device is delivered to the destination site, the product is unfolded. The packing material and the device enclosure are integrated to reduce wear and tear, waste, as well as provide a new finish for each use. The packing/enclosure is to be constructed of a recycled/recyclable material. Once the device is unpacked and turned on, it seeks the predetermined mode of communication, through a phone line, wireless LAN, bluetooth, cellular connection or an as yet developed method. Once connected the device sends the initiator an email message which can be clicked to access the units controls. When the email is clicked the senders web browser is activated and accesses the unit. The initiator's web browser serves as the units controller with a graphical user interface. The interface contains the video image from the camera, as well as the specific tasks initiated by the sender.

1. What I claim as my invention is an electronic device that is designed to take the place of sending an individual and performing the various tasks remotely.

2. What I claim as my invention is this electronic device is controlled by the sender's computer, or other device, and performs audio and visual conferencing tasks as well as other specialized tasks.

3. What I claim as my invention is the other specialized tasks performed by are, but not limited to, printing, controlling a projector, audio/visual conferencing, computer file management, distance learning functions, distance medicine functions, disaster management, cellular communications, and product presentation.

4. What I claim as my invention is the business model of renting said electronic device to be delivered from a locally available source.

5. What I claim as my invention is the integration of packaging and housing of said electronic device to a recyclable material that is changed each time it is used in order to save on weight, wear and tear, as well as materials.

6. What I claim as my invention is said packaging/housing is delivered folded flat and unfolds to serve as the stand for the electronic device.

7. What I claim as my invention is the compartmentalization of the electronic components utilized in said electronic device. These components are intended for specific purposes that include but not limited to, printing, controlling a projector, audio/visual conferencing, computer file management, distance learning functions, distance medicine functions, disaster management, cellular communications and product presentation.

8. What I claim as my invention is said compartmentalized electronic components are sealed, standardized components that are easily exchanged, upgraded, and adaptable to emerging technologies.

9. What I claim as my invention is in addition to these electronic components; there is a display module and a visualization module, a viewing module, and a task/power/speaker module.

10. What I claim as my invention is said display module is standardized and interchangeable, as well upgradeable. This unit contains a touch sensitive LCD screen as well as the required hardware and software for this unit.

11. What I claim as my invention is said visualization module contains a 3-camera panorama lens that enables the controller to pan the display through 160 degrees enabling a viewer to view a larger area. The image is processed on the controlling computer with a software solution that creates a smooth natural image.

12. What I claim as my invention is said electronic device to understand where it is and the tasks it is required to perform. When activated the device connects to the Internet (either through a phone line, wireless LAN, bluetooth, or cellular connection or as yet developed method) and accesses its online file as to its task and the individual who rented the device. A message is sent to that individual and enables the renter to remotely access the unit and control its functions.
